(19) United States
(12) Patent Application Publication
(10) Pub. No.: US 2019/0140092 A1
(43) Pub. Date: May 9, 2019

(54) SILICON CARBIDE SEMICONDUCTOR DEVICE AND METHOD OF MANUFACTURING SAME

(71) Applicant: Fuji Electric Co., Ltd., Kanagawa (JP)

(72) Inventors: Makoto UTSUMI, Nagano (JP); Yoshiyuki SAKAI, Nagano (JP)

(73) Assignee: Fuji Electric Co., Ltd., Kanagawa (JP)

(21) Appl. No.: 16/155,070

(22) Filed: Oct. 9, 2018

(30) Foreign Application Priority Data
Nov. 8, 2017 (JP) 2017-215758

(51) Int. Cl. H01L 29/78; H01L 29/423; H01L 29/16; H01L 29/66; H01L 29/10; H01L 29/08

(52) U.S. Cl. CPC H01L 29/7813; H01L 29/4236; H01L 29/1608; H01L 29/086; H01L 29/66734; H01L 29/1095; H01L 29/1033; H01L 29/66068

(57) ABSTRACT

A silicon carbide semiconductor device includes: a drift region of a first conductivity type; a base region of a second conductivity type disposed on the drift region; a main electrode contact region of the first conductivity type selectively embedded in a top of the base region at a higher impurity density than the drift region; a trench having a round part on a top surface side of the main electrode contact region to a level that is shallower than a depth of the main electrode contact region, the trench going from the round part through the base region and having a bottom that reaches the drift region; and an insulated gate structure provided on an inner side of the trench. A smallest radius of curvature of the round part is greater than a relatively high impurity region of the main electrode contact region.

### BACKGROUND OF THE INVENTION

### Technical Field

The present invention relates to the trench structure of a trench gate type semiconductor device that uses silicon carbide (SiC) and to a method of manufacturing the same.

### Background Art

In a trench gate type MOS transistor, the channel region is formed on the side surfaces of a trench dug into a semiconductor layer. The trench gate type MOS transistor can be made to have higher channel density than a planar type MOS transistor due to shrinking the cell pitch, and thus a decrease in ON resistance can be expected. When using a SiC semiconductor layer, dry etching is used to form the trench. The trench is dug approximately perpendicularly to the semiconductor layer, and the opening and bottom corners of the trench are approximately at right angles to each other. The trench side surfaces are susceptible to roughening. The roughness of the side surfaces and the corners of the openings and bottoms are likely to cause the gate breakdown voltage to drop due to the concentration of electric fields.

Patent Document 1 proposes performing a thermal oxidation step two times in order to round the opening and bottom of the trench into a round shape so as to improve gate characteristics. Patent Document 2 discloses performing a thermal treatment in a gas atmosphere such as argon (Ar) or hydrogen (H₂) in order to make the opening and bottom of the trench a round shape so as to improve the gate breakdown voltage. Patent Document 3 also discloses performing a thermal treatment in an Ar atmosphere to make the opening and bottom of the trench a round shape.

As described above, rounding of the trench is necessary for the gate insulating film to have a high withstand voltage and to have high reliability. In Patent Document 1, the thermal oxidation is used as a method to process and clean the channel region surface, but if the channel region surface is excessively thermally oxidized, then the intrusion of oxygen and lattice mismatching will occur inside the semiconductor layer, thus increasing the channel resistance. Furthermore, in Patent Documents 2 and 3, the rounding by the thermal treatment in the gas atmosphere uses diffusion or rearrangement of atoms in the surface. Due to this, n-type impurities diffuse from the source region to the channel region, p-type impurities detach from the channel region, and a portion of the p-type trench side surfaces changes to n-type or i-type. Thus, this becomes the cause of frequent leakage in the channel region.

### RELATED ART DOCUMENTS

### Patent Documents

Patent Document 1: Japanese Patent Application Laid-Open Publication No. H7-263692

Patent Document 2: Japanese Patent No. 5209152

Patent Document 3: Domestic Re-publication of PCT International Application No. 2016/038833

### SUMMARY OF THE INVENTION

In view of the aforementioned problems, the present invention aims at providing a highly reliable SiC semiconductor device and a method for manufacturing the same that can suppress a reduction in gate breakdown voltage, prevent an increase in channel resistance, and stabilize electrical characteristics.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a silicon carbide semiconductor device, including: (a) a drift region made of a silicon carbide semiconductor of a first conductivity type; (b) a base region made of the silicon carbide semiconductor of a second conductivity type disposed on the drift region; (c) a main electrode contact region made of the silicon carbide semiconductor of the first conductivity type selectively embedded in a top of the base region at a higher impurity density than the drift region; (d) a trench penetrating through the main electrode contact region and the base region and reaching the drift region, the trench having a round part on a top surface side of the main electrode contact region to a level that is shallower than a bottom of the main electrode contact region; and (e) an insulated gate structure provided on an inner side of the trench, wherein a smallest radius of curvature among circular arcs approximating a curved surface of the round part of the trench is greater than a depth of a relatively high impurity region of the main electrode contact region, the relatively high impurity region of the main electrode contact region being defined as a region having an impurity concentration of approximately 1×10¹⁸ cm⁻³ or greater.

In another aspect, the present disclosure provides a method of manufacturing a silicon carbide semiconductor device, the method including: (a) forming a drift region made of a silicon carbide semiconductor of a first conductivity type; (b) forming a base region made of the silicon carbide semiconductor of a second conductivity type on a top surface side of the drift region; (c) selectively embedding a main electrode contact region made of the silicon carbide semiconductor of the first conductivity type in a top of the base region at a higher impurity density than the drift region; (d) forming a trench penetrating through the main electrode contact region and the base region and reaching the drift region; (e) forming a round part in the trench by rounding a corner of an opening in the trench opened in the top surface of the main electrode contact region via a thermal treatment in a hydrogen atmosphere, the round part being formed in the opening to a level that is shallower than a bottom of the main electrode contact region; (f) performing a thermal oxidation treatment of an inner wall of the trench and then removing a thermal oxide film formed in the thermal oxidation treatment; and (g) forming an insulated gate structure on an inner side of the trench, wherein (h) a smallest radius of curvature among circular arcs approximating a curved surface of the round part of the trench is greater than a depth of a relatively high impurity region of the main electrode contact region, the relatively high impurity region of the main electrode contact region being defined as a region having an impurity concentration of approximately 1×10¹⁸ cm⁻³ or greater.

The present invention makes it possible to provide a highly reliable SiC semiconductor device and a method for manufacturing the same that can suppress a reduction in gate breakdown voltage, prevent an increase in channel resistance, and stabilize electrical characteristics.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a cross-sectional view of main components showing one example of a semiconductor device according to an embodiment of the present invention.

FIG. 2 is a cross-sectional view of a step for describing one example of a method of manufacturing the semiconductor device according to the embodiment of the present invention.

FIG. 3 is a cross-sectional view of a step after FIG. 2 for describing one example of the method of manufacturing the semiconductor device according to the embodiment of the present invention.

FIG. 4 is a cross-sectional view of a step after FIG. 3 for describing one example of the method of manufacturing the semiconductor device according to the embodiment of the present invention.

FIG. 5 is a cross-sectional view of a step after FIG. 4 for describing one example of the method of manufacturing the semiconductor device according to the embodiment of the present invention.

FIG. 6 is a cross-sectional view of a step after FIG. 5 for describing one example of the method of manufacturing the semiconductor device according to the embodiment of the present invention.

FIG. 7 is a cross-sectional view of a step after FIG. 6 for describing one example of the method of manufacturing the semiconductor device according to the embodiment of the present invention.

FIG. 8 is a SEM image of a cross section of the trench shown in FIG. 7.

FIG. 9 is a schematic view for describing the cross-sectional shape of a trench according to the embodiment of the present invention and trenches of comparative examples.

FIG. 10 is a view showing the impurity concentration distribution via a SIMS analysis from the source region surface in the semiconductor device according to the embodiment of the present invention.

FIG. 11 is a view showing Id-Vg characteristics of the semiconductor device according to the embodiment of the present invention and semiconductor devices of comparative examples.

FIG. 12 is a view showing correlation between the threshold voltage and ON resistance of the semiconductor device according to the embodiment of the present invention and semiconductor devices of comparative examples.

FIG. 13 is a table showing measurement results of the round shape and electrical characteristics of the semiconductor device according to the embodiment of the present invention and semiconductor devices of comparative examples.

### DETAILED DESCRIPTION OF EMBODIMENTS

Embodiments of the present invention will be explained below with reference to the drawings. In the drawings, portions that are the same or similar will be assigned the same or similar reference characters and redundant explanations will be omitted. However, the drawings are schematic, and the relationship between thickness and planar dimensions, the ratio of the thickness of each layer, etc. may differ in practice. Furthermore, there can be parts for which the relationship between dimensions, ratios, etc. differ even among the drawings. The embodiment shown below illustratively indicates a device and a method for carrying out the technical idea of the present invention, and the technical idea of the present invention is not limited to the material, shape, structure, arrangement, etc. of the constituent components described below.

In addition, the definition of directions such as up-down in the description below are merely definitions for convenience of explanation and do not limit the technical idea of the present invention. For example, if an object is observed after being rotated 90°, up-down is converted to left-right, and if observed after being rotated 180°, up-down is inversed. Further, in the description below, the first conductivity type is illustratively described as n-type and the second conductivity as p-type. However, an inverse relationship may be selected for the conductivity types, where the first conductivity type is p-type and the second conductivity type is n-type. A “+” or “-” attached to an “n” or “p” signifies that the impurity element density is higher or lower, respectively, than a semiconductor region not having the “+” or “−”. However, this does not mean that semiconductor regions that are both labelled “n” have exactly the same impurity densities.

In the description below, “main electrode region” (also referred to as “main electrode contact region”) is a concept that comprehensively includes either a “second main electrode region” or “first main electrode region” with which an ohmic electrode makes ohmic contact. For example, a semiconductor region with a high impurity density of around 5×10¹⁷ cm ⁻³ to 1×10²¹ cm⁻³ would be either the “second main electrode region” or “first main electrode region.” An ordinary three-terminal semiconductor device or the like has two main electrode regions: a main electrode region emitting a main current that flows through a carrier traveling region; and a main electrode region that receives the carriers constituting the main current. One of these can be defined as the “second main electrode region,” and the other as the “first main electrode region.” In other words, the “second main electrode region” means a semiconductor region serving as either a source region or a drain region in a field effect transistor (FET) or static induction transistor (SIT). In an insulated gate bipolar transistor (IGBT), “second main electrode region” means a semiconductor region serving as either an emitter region or a collector region. In a static inductor thyristor (SI thyristor) or gate turn-off thyristor (GTO), “second main electrode region” means a semiconductor region serving as either the anode region or cathode region. The “first main electrode region” means, in a FET or SIT, a semiconductor region serving as whichever of the source region or drain region that is not the second main electrode region. In an IGBT, “first main electrode region” means a region serving as whichever of the emitter region or collector region that is not the second main electrode region. In a SI thyristor or GTO, “first main electrode region” means a region serving as whichever of the anode region or cathode region that is not the second main electrode region. Thus, if the “second main electrode region” of the present invention is the source region, then “first main electrode region” means the drain region. If the “second main electrode region” is the emitter region, then “first main electrode region” means the collector region. If the “second main electrode region” is the anode region, then “first main electrode region” means the cathode region. If the bias relationship is interchanged, then in many cases, the function of the “second main electrode region” and the function of the “first main electrode region” are interchangeable.

### (Semiconductor Device)

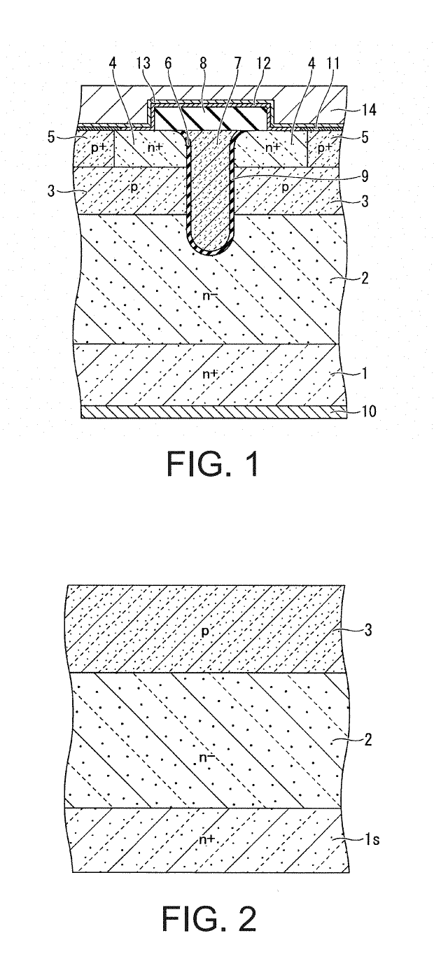

A semiconductor device according to an embodiment of the present invention will be described using a MOS transistor having a trench gate. As shown in FIG. 1, the semiconductor device according to the embodiment of the present invention includes an active region (1, 2, 3, 4, 5), an insulating layer film (interlayer insulating film) 8, surface electrode layer 14, and rear surface electrode layer 10. The active region (1, 2, 3, 4, 5) has a drain region (first main electrode region) 1 of a first conductivity type (n⁺), a carrier traveling region (2, 3) above the drain region 1, and a source region (second main electrode contact region) 4 above the carrier traveling region (2, 3). The carrier traveling region (2, 3) includes a drift region (first semiconductor layer) 2 of the first conductivity type (n⁻), and a base layer (second semiconductor layer) 3 of a second conductivity type (p-type). The source region 4 is provided on top of the carrier traveling region (2, 3) and is a semiconductor region of a higher impurity density than the carrier traveling region (2, 3). In the embodiment of the present invention, attention is focused on the top structure of the structure shown in FIG. 1, and thus the source region (second main electrode contact region) 4 is defined as the “main electrode (contact) region.” A base contact region 5 of the second conductivity type (p⁺) is disposed adjacent to the main electrode contact region 4. A surface electrode layer 14 is provided on the top surface of the main electrode region 4. The drain region 1 is a semiconductor region of a higher impurity density than the carrier traveling region (2, 3). A rear surface electrode layer 10 is provided on the bottom surface of the drain region 1.

A trench 9 is provided going through the base region 3 from the top surface of the source region 4 until the bottom of the trench reaches the drift region 2. The trench 9 has a round part on the top surface side of the source region 4 at level that is shallower than the depth of the source region 4. “Round part” indicates the section with the curved surface shape that has a rounded corner. An insulated gate structure (6, 7) is provided on the inner side of the trench 9. The insulated gate structure (6, 7) has a gate insulating film 6 provided on the bottom surface and side surfaces of the trench 9, and a gate electrode 7 embedded inside the trench 9 with the gate insulating film 6 interposed therebetween. In FIG. 1, a single trench is shown, but in practice there may be a large number of trenches, so as to form a multi-channel structure. An insulating film layer (interlayer insulating film) 8 is selectively disposed on the gate electrode 7 so as to expose a portion of the main electrode region 4, and a contact hole is provided in the insulating film layer 8. The insulating film layer 8 also has a contact hole for the gate electrode 7, but a description of the structure of the ohmic electrode on the gate electrode 7 side is omitted. In the contact hole on the source region 4 side, the insulating film layer 8 covers a portion of the top surface of the source region 4 on both sides. The top surface of the source region 4 forms the main surface of the active region (1, 2, 3, 4, 5).

The trench 9 has a width of around 0.5 μm to 1 μm, for example, and a depth of around 1 μm to 2 μm, for example. However, it shall be understood from the description below that the width or depth of the trench 9 of the present invention is not limited to these values. In the embodiment of the present invention, the trenches 9 of respective unit cell structures are arrayed in a stripe pattern in a planar pattern, but the present invention is not limited to this. For example, the trench 9 may have a polygonal planar pattern such as a rectangular planar pattern or a hexagonal planar pattern.

In the embodiment of the present invention, the drain region 1 is formed of a semiconductor substrate made of SiC (SiC substrate), and the carrier traveling region layer (2, 3) and main electrode region 4 are formed of an epitaxial layer made of SiC (SiC layer). SiC crystals exhibit crystal polymorphism, the main polytypes being 3C, which is cubic, and 4H and 6H, which are hexagonal. It is reported that the bandgap at room temperature is 2.23 eV for 3C-SiC, 3.26 eV for 4H-SiC, and 3.02 eV for 6H-SiC. In the embodiment of the present invention, 4H-SiC is used in the description. Furthermore, the description uses the Si-plane as the main surface of the active region (1, 2, 3, 4, 5) and the m-plane as the side surfaces of the trench 9 serving as the channel.

The gate insulating film 6 is a silicon oxide film (SiO₂ film) or the like. The thickness of the gate insulating film 6 is around 20 nm to 150 nm, for example. The gate electrode 7 is a polysilicon layer (doped polysilicon layer), or the like, to which n-type impurities have been added. The material of the surface electrode layer 14 can be aluminum (Al), or an Al alloy such as Al—Si, Al-copper (Cu), or Al—Cu—Si, for example. A source contact layer 11 and a barrier metal layer 12 serving as the base metal are disposed below the surface electrode layer 14. The source contact layer 11 is disposed so as to metallurgically contact the end of the source region 4 and the base contact region 5. The barrier metal layer 12 metallurgically contacts the source region 4 and extends from the source region 4 so as to cover the side surfaces and top surface of the insulating film layer 8. The surface electrode layer 14 is disposed so as to cover the source contact layer 11 and barrier metal layer 12. A top barrier metal layer 13 may be disposed between the source contact layer 11 and barrier metal layer 12 and the surface electrode layer 14. The top barrier layer 13 should be a titanium (Ti)/TiN/Ti laminate structure. For example, the source contact layer 11 can be a nickel silicide (NiSiₓ) film, the barrier metal layer 12 can be a titanium nitride (TiN) film, and the surface electrode layer 14 can be an aluminum (Al) film. The source contact layer 11 is formed by depositing a metal layer such as a Ni film by sputtering or vapor deposition, using photolithography and RIE etc. to pattern the metal layer, and performing a thermal treatment at e.g. 1000° C. with RTA. The barrier metal layer 12 is formed by depositing a metal layer such as a TiN film via sputtering or the like, and photolithography and RIE etc. are used to pattern the metal layer. For example, the rear surface electrode 10 can be a single layer film made of gold (Au), or a metal film in which Al, nickel (Ni), and Au have been laminated in the stated order. A metal plate such as molybdenum (Mo) or tungsten (W) may be further laminated on the bottommost layer thereof.

The insulating film layer 8 can be a silicon oxide film (SiO₂ film) that do not contain phosphorous (P) or boron (B), which is referred to as so-called “NSG.” However, the insulating film layer 8 may be a silicon oxide film (PSG) to which phosphorous has been added, a silicon oxide film (BSG) to which boron has been added, a silicon oxide film (BPSG) to which boron and phosphorous have been added, a silicon nitride (Si₃N₄) film, etc. Furthermore, the insulating film layer 8 can be a composite film in which a plurality of types of films have been selected and combined among the NSG film, PSG film, BSG film, BPSG film, Si₃N₄ film, etc.

As shown in FIG. 1, in the semiconductor device according to the embodiment of the present invention, the trench 9 has an opening provided in the main surface of the source region 4, and the bottom surface of the trench is positioned in the top of the drift region 2. Round parts that round the corners of the opening and bottom surface are provided. The curved surface structure formed by the round part can suppress the concentration of electric fields on the periphery of the gate electrode structure and prevent a reduction in the gate breakdown voltage. Furthermore, the round part on the main surface side of the source region 4 is provided in the source region 4 so as to be separate from the base region 3. Thus, as described later, it is possible to reduce ON resistance and to prevent channel leakage.

### (Method of Manufacturing Semiconductor Device)

Next, the cross-sectional views of the steps shown in FIGS. 2 to 7 will be used to describe one example of a method of a manufacturing the semiconductor device according to the embodiment of the present invention for a trench gate type MOSFET. The method of manufacturing the trench gate MOSFET described below is one example, and various other types of methods of manufacturing can be performed, including a modification example of this method, within the scope set forth in the claims.

First, as shown in FIG. 2, an n⁺ substrate (SiC substrate) is to which an n-type impurity such as nitrogen (N) has been added is prepared. The n-type drift region 2 is epitaxially grown on the top surface of the substrate ls. The base region 3 is formed by ion implantation or epitaxial growth etc. on the top surface of the drift region 2 to form the basic structure of the carrier traveling region (2, 3).

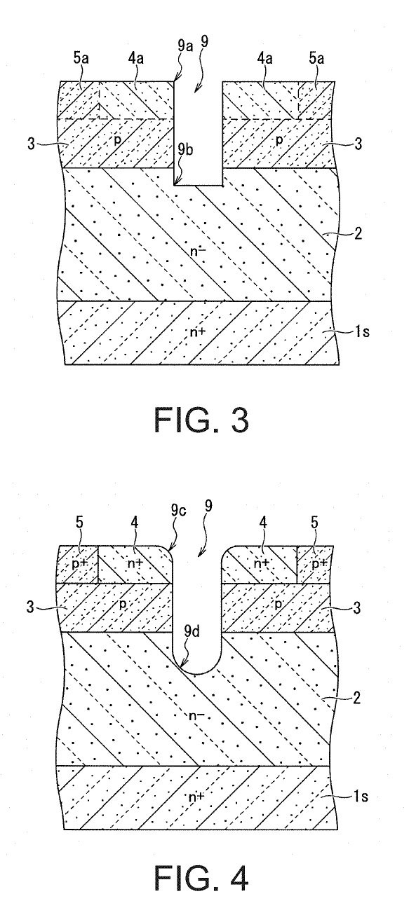

As shown in FIG. 3, photolithography and ion implantation etc. are used to selectively form, in the top of the base region 3, an impurity region 4a where n-type impurities have been implanted at a high impurity density, and an impurity region 5a where p-type impurities have been implanted at a high impurity density. The diffusion coefficient of impurity elements in SiC is small, and thus it is preferable to use multiple-stage ion implantation where ion implantation is performed a plurality of times while changing the acceleration voltage. Next, photolithography and dry etching such as reactive ion etching (RIE) or the like are used to selectively form the trench 9 going from an opening defined in the top surface of the impurity region 4a and through the impurity region 4a and base region 3, the bottom of the trench reaching the top of the drift region 2. A corner 9a of the opening in the trench 9 and a corner 9b of the bottom of the trench are formed at an angle that is nearly a right angle.

Next, a thermal treatment is performed in an H₂ atmosphere. As shown in FIG. 4, this thermal treatment forms corners 9c, 9d where the corners 9a, 9b have been rounded in the trench 9. The termination of the corner 9c of the opening is separate from the base region 3, and the round part is provided on the opening side of the source region at a level that is shallower than the depth of the source region 4. Furthermore, the thermal treatment activates the impurities in the impurity regions 4a, 5a, and respectively forms the n⁺ source region 4 and p⁺ base contact region 5. The thermal treatment step for forming the source region 4 and base contact region 5 may be performed before opening the trench 9, but this is not preferable because there would be two thermal treatments in total including the thermal treatment in the H₂ atmosphere. If the thermal treatment step for forming the source region 4 and base contact region 5 is performed after forming the trench 9, then during forming of the trench 9, the impurity ions for forming the source region 4 and base contact region 5 will not be activated. However, for convenience, the present invention is viewed to have a configuration where the source region 4 and base contact region 5 have been formed, including such a state where the impurity ions are not yet activated. Due to this, regardless of the procedure, in the stage for forming the trench 9, it is possible to view the source region 4 and base contact region 5 as being embedded in the top of the base region 3.

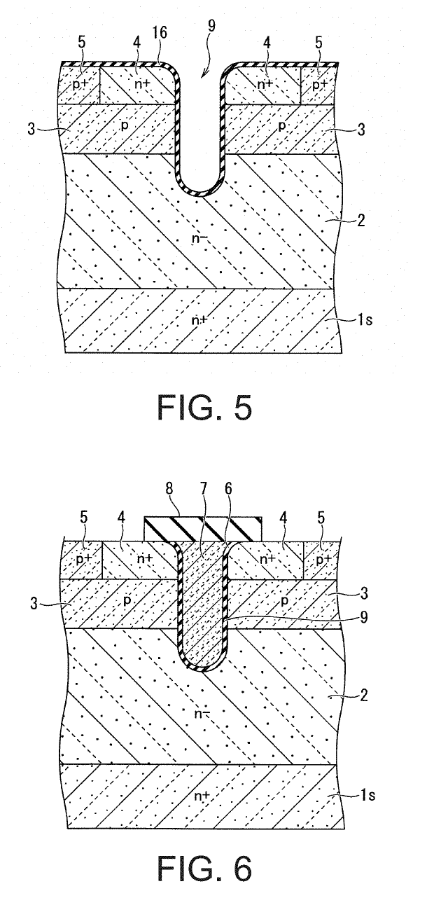

As shown in FIG. 5, thermal oxidation is used to form a thermal oxide film on the bottom surface and side surfaces of the trench 9 and the top surface of the base region 3, thus forming a field insulating film 16. The thickness of the thermal oxide film is 3 nm to 25 nm, and thus, as necessary, the field insulating film 16 may be formed on the bottom surface and side surfaces of the trench 9 and the top surface of the base region 3 by depositing a CVD insulating film after the thermal oxidation has been performed. Thereafter, photolithography and wet etching etc. are used to remove the field oxide film 16 in locations except for the trench 9, and the field oxide film 16 inside the trench 9 is defined as the gate insulating film 6.

As shown in FIG. 6, chemical vapor deposition (CVD) and etch-back etc. are used to embed polysilicon inside the trench 9 and form the insulated gate structure (6, 7). Thereafter, CVD or the like is used to deposit an insulating film such as a SiO₂ film on the top surface of the source region 4 and base contact region 5. Photolithography and dry etching etc. are used to selectively form the insulating film layer 8 on the gate insulating film 6 and gate electrode 7. As shown in FIG. 6, a contact hole where the insulating film layer 8 is not present is provided. This contact hole exposes the base contact region 5 and a portion of the source region 4.

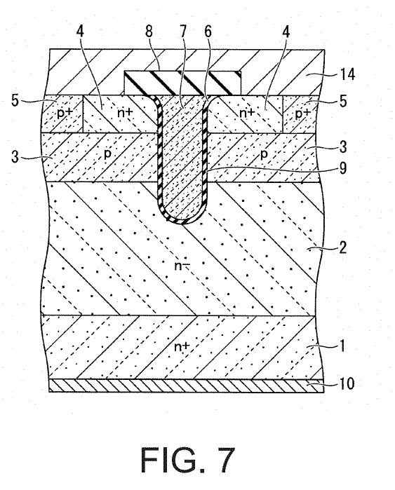

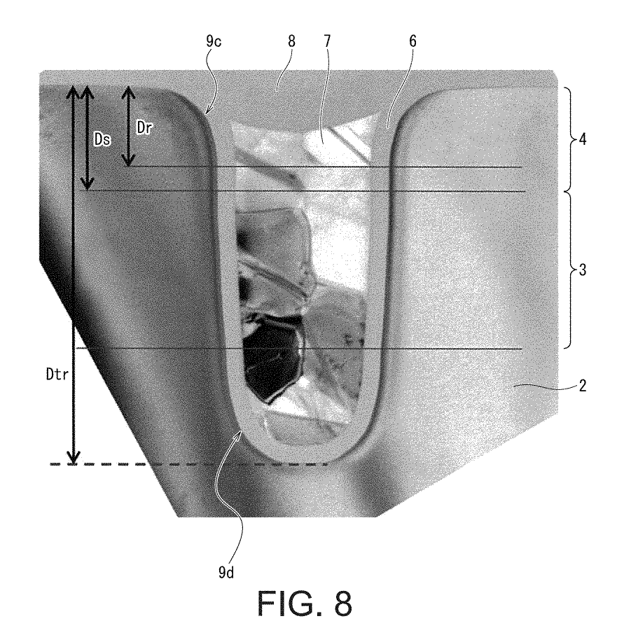

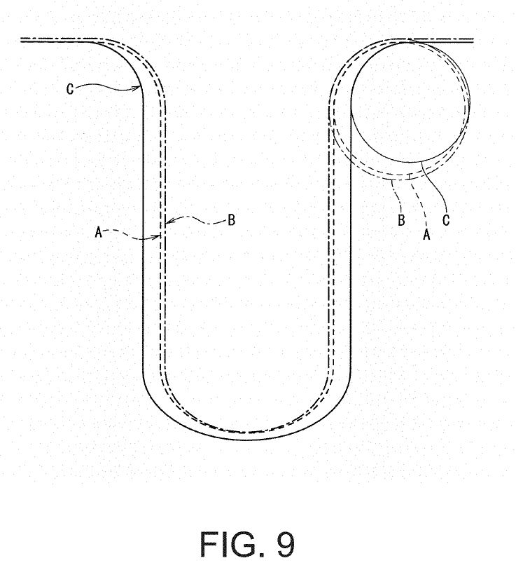

As shown in FIG. 7, chemical mechanical polishing (CMP) or the like is used to perform thickness adjustment by polishing the bottom surface of the substrate is and to form the drain region 1. Thereafter, as shown in FIG. 9, sputtering or vacuum deposition etc. is used to form a rear surface electrode layer (drain electrode layer) 10 made of Au etc. on the bottom surface of the drain region 1. Furthermore, sputtering or vacuum deposition etc. is used to deposit a metal film such as Al to form the surface electrode layer 14. This completes the semiconductor device according to the embodiment of the present invention. An order may be used in which the step of forming the drain region 1 by polishing the bottom surface of the substrate is is performed after the step of forming the surface electrode layer 14, and thereafter the rear surface electrode layer 10 made of Au etc. is formed on the bottom surface of the drain region 1.

FIG. 8 shows a cross-sectional SEM image of the trench 9 in a working example of the present invention. As shown in FIG. 8, the corners 9c, 9d of the opening and bottom of the trench 9 have a rounded curved surface structure. A depth Dtr of the trench 9 is approximately 1.62 μm, a depth Ds of the source region 4 is approximately 0.45 μm, and a depth Dr of the round part is approximately 0.35 μm. Thus, it can be understood that the curved surface portion defining the round part is formed to a level shallower than the depth of the source region 4, and is separated from the base region 3, which is the channel region, by approximately 0.1 μm. It is desirable that the depth Dr of the round part be separated by approximately 0.1 μm or more from the base region 3. If the thermal treatment for rounding is performed for a long period of time, diffusion or recombination of atoms in the inner wall surface of the trench 9 will increase, thus changing the channel region to n-type or i-type, causing leakage of the channel region, or the like. Accordingly, if the depth Dr of the round part is set to the depth Ds of the source region 4 or beyond, degradation of electrical characteristics may occur.

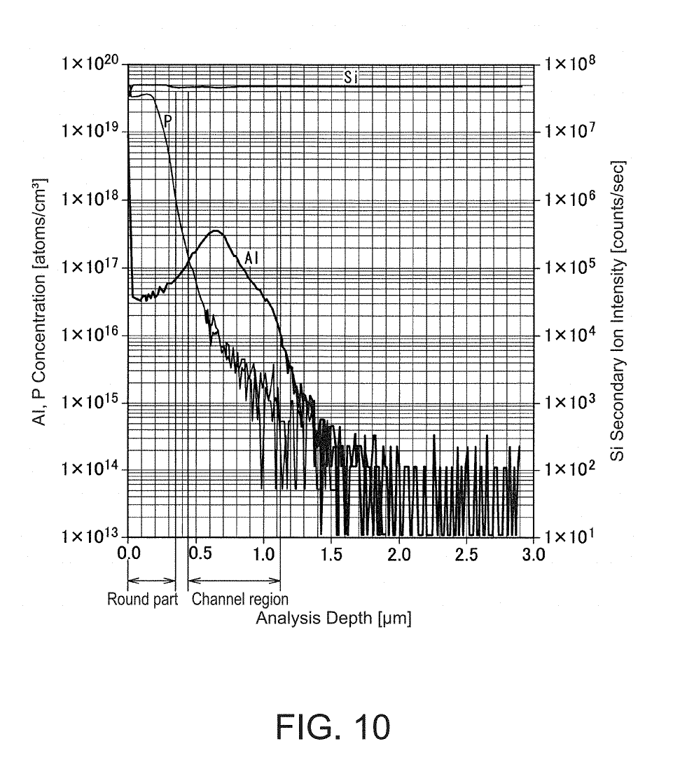

Results of analysis of impurity distribution using the working example shown in FIG. 8 and using secondary ion mass spectrometry (SIMS) are shown in FIG. 10. As shown in FIG. 10, phosphorous (P), which is an n-type impurity, is distributed in the surface side of the source region 4 at approximately 3×10¹⁹ cm⁻³. At the depth of the round part, the distribution is approximately 1×10¹⁸ cm⁻³. Al, which is a p-type impurity, has a distribution inside the source region 4 of approximately 1×10¹⁷ cm⁻³ or less, and a distribution inside the base region 3 of approximately 0.1 to 3×10¹⁷ cm⁻. At the boundary between the source region 4 and base region 3, the distribution density of P and Al is around the same: approximately 1×10¹⁷ cm⁻³.

FIG. 9 shows the trench shape of working example “A” shown in FIG. 8 along with comparative examples “B” and “C.” As described above, in working example A, after the thermal treatment for rounding, thermal oxidation is performed one time as a surface removal treatment for the trench 9 side surface. In comparative example B, only the thermal treatment for rounding is performed, and thermal oxidation is not performed. In comparative example C, conventional parameters are used, or namely, thermal oxidation is performed three times after the thermal treatment for rounding. As shown in FIG. 9, the width of the trench is narrowest in comparative example B where thermal oxidation is not performed, and widest in comparative example C where thermal oxidation is performed three times. FIG. 9 also shows the circle of the smallest radius of curvature among circular arcs approximating the curve of the round part. The smallest value of the radius of curvature is confirmed to substantially correspond to the depth level of the round part. As shown in FIG. 9, working example A and comparative example B have almost no difference in the radius of curvature. The radius of curvature is small in comparative example C. The reason that the radius of curvature is small is due to the difference in oxidation rates of the m-plane and Si-plane. The results of evaluating electrical characteristics are that working example A has low ON resistance and little channel leakage. Comparative example B has channel leakage. Comparative example C has an increased ON resistance. The surface roughness of the channel region in working example A is 1.2 nm or lower at the maximum cross-sectional height Rt, which is enough to obtain a sufficiently smooth surface in a single thermal oxidation treatment.

In the thermal treatment for rounding, the diffusion and recombination of the atoms changes the trench inner wall surface to n-type or i-type. Due to this, in comparative example B, where the trench inner wall is not removed by the thermal oxidation treatment, channel leakage occurs. Furthermore, in the conventional parameters of comparative example C, a thermal oxidation treatment where the trench side surface, which is the channel surface, is removed and cleaned is performed three times. If thermal oxidation is performed excessively in this manner, channel resistance will increase due to the intrusion of oxygen or lattice mismatching inside the channel region. In working example A, the thermal oxidation treatment is performed one time, and 2 nm to 20 nm of the side surface of the trench inner wall is removed. As a result, in the embodiment, there is little channel leakage, and it was possible to reduce ON resistance. The thickness of the removed oxide film is 3 nm to 25 nm, which is approximately 2 nm to approximately 20 nm when converted (2/3 times) to the thickness of SiC.

In order to investigate the influence of the number of times that the thermal oxidation treatment is performed as a surface removal treatment after formation of the round part, a semiconductor device was prototyped with all steps being the same, including the thermal treatment parameters, except for the number of times the thermal treatment was performed, and then the electrical characteristics were evaluated. The thermal treatment is performed three times in the conventional parameters. In the embodiment of the present invention, the thermal treatment is performed only one time. For comparison, an example has been added where the thermal treatment was performed two times. The results of evaluating the depth of the round part formed in the source region were that the depth of the round part was approximately 0.35 μm, 0.3 μm, and 0.25 μm for elements where the thermal oxidation treatment was performed one time, two times, and three times, respectively.

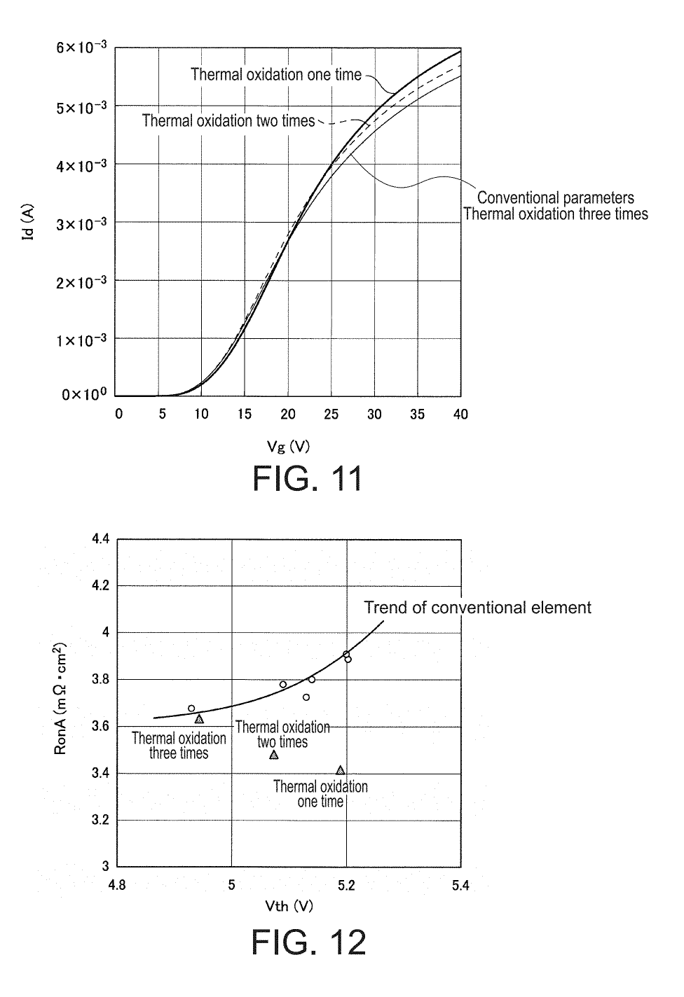

FIG. 11 is the relationship between drain current and gate voltage (Id-Vg characteristics) measured by a monitor MOS transistor provided on the prototype substrate. As shown in FIG. 11, it can be understood that when the number of times of the thermal oxidation treatment is increased from one time to three times, the drain current is reduced, and thus channel resistance increases. FIG. 12 shows the correlation between the threshold voltage Vth and the ON resistance RonA per unit area of a semiconductor device of a 3 mm chip fabricated on the prototype substrate. The value of the ON resistance RonA and threshold voltage Vth shown in FIG. 12 is the median value for each distribution. As shown in FIG. 12, it can be understood that as the number of the thermal oxidation treatment is increased, the threshold voltage Vth decreases, and the ON resistance RonA is reduced. FIG. 12 also shows the trend in correlation for Vth-RonA of a conventional element where the thermal oxidation treatment is performed three times. In the conventional element, when the threshold voltage Vth increases, the ON resistance RonA has a tendency to increase. For example, it can be understood that if the threshold voltage Vth is approximately 5.2 V, then in the conventional element the ON resistance RonA is approximately 3.9 mΩcm², but in the parameter corresponding to the embodiment of the present invention where the thermal oxidation treatment is performed one time, ON resistance RonA is approximately 3.4 mΩcm², which is a reduction in ON resistance.

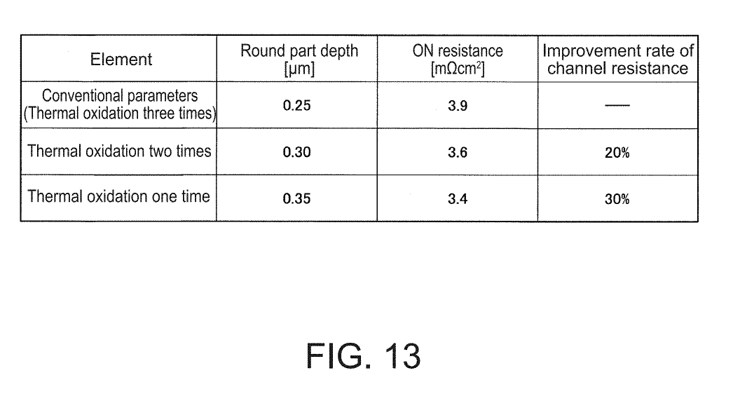

FIG. 13 shows results from evaluating the prototyped elements where the number of times the thermal oxidation treatment was performed was changed. As shown in FIG. 13, the depth of the round part of the trench is approximately 0.25 μm in the conventional element, but is approximately 0.30 μm and approximately 0.35 μm in the elements where the thermal oxidation treatment was performed two times and one time, respectively, which is an increase in the depth. The ON resistance RonA is approximately 3.4 mΩcm², approximately 3.6 mΩcm², and approximately 3.9 mΩcm² when the thermal oxidation treatment is performed one time, two times, and three times, respectively, and it can be understood that an increase in the number of times the thermal oxidation treatment is performed leads to an increase in ON resistance. The improvement rate of the channel resistance relative to the conventional element is 30% and 20% when the thermal oxidation treatment is performed one time and two times, respectively. In the embodiment of the present invention, after the thermal treatment for rounding is performed, the thermal oxidation treatment is performed only one time as a removal treatment for the surface of the channel region. As a result, it is possible to suppress a reduction in the gate breakdown voltage, to prevent an increase in channel resistance, and furthermore, to prevent channel leakage, and to reduce ON resistance.

### (Other Embodiments)

As described above, an embodiment of the present invention was disclosed, but the description and drawings forming a portion of this disclosure shall not be construed as limiting the present invention. Various substitute embodiments, examples, and applied techniques should be clear to a person skilled in the art based on this disclosure.

For example, a MOS transistor, which is an individual semiconductor element, was illustratively described in the embodiment above, but a semiconductor device serving as the target for application of the present invention is not limited to an individual semiconductor element. The semiconductor device of the present invention can be applied to semiconductor devices having various types of trench structures, such as an IGBT having a trench structure where an electrode is disposed on a semiconductor layer with an insulating film interposed therebetween, for example.

Thus, it goes without saying that the present invention includes various embodiments etc. not disclosed here, such as configurations in which various configurations described in the embodiments and respective modification examples above have been applied as desired. Accordingly, the technical scope of the present invention is determined solely by the invention-defining matters within a reasonable scope of the claims from the descriptions above.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A silicon carbide semiconductor device, comprising:
a drift region made of a silicon carbide semiconductor of a first conductivity type;
a base region made of the silicon carbide semiconductor of a second conductivity type disposed on the drift region;
a main electrode contact region made of the silicon carbide semiconductor of the first conductivity type selectively embedded in a top of the base region at a higher impurity density than the drift region;
a trench penetrating through the main electrode contact region and the base region and reaching the drift region, the trench having a round part on a top surface side of the main electrode contact region to a level that is shallower than a bottom of the main electrode contact region; and
an insulated gate structure provided on an inner side of the trench, wherein a smallest radius of curvature among circular arcs approximating a curved surface of the round part of the trench is greater than a depth of a relatively high impurity region of the main electrode contact region, the relatively high impurity region of the main electrode contact region being defined as a region having an impurity concentration of approximately 1×10¹⁸ cm⁻³ or greater.

2. The silicon carbide semiconductor device according to claim 1, wherein inside the trench, a termination position of the curved surface that defines the round part is separated from the base region by at least 0.1 μm.

3. A method of manufacturing a silicon carbide semiconductor device, the method comprising:
forming a drift region made of a silicon carbide semiconductor of a first conductivity type;
forming a base region made of the silicon carbide semiconductor of a second conductivity type on a top surface side of the drift region;
selectively embedding a main electrode contact region made of the silicon carbide semiconductor of the first conductivity type in a top of the base region at a higher impurity density than the drift region;
forming a trench penetrating through the main electrode contact region and the base region and reaching the drift region;
forming a round part in the trench by rounding a corner of an opening in the trench opened in the top surface of the main electrode contact region via a thermal treatment in a hydrogen atmosphere, the round part being formed in the opening to a level that is shallower than a bottom of the main electrode contact region;
performing a thermal oxidation treatment of an inner wall of the trench and then removing a thermal oxide film formed in the thermal oxidation treatment; and
forming an insulated gate structure on an inner side of the trench, wherein a smallest radius of curvature among circular arcs approximating a curved surface of the round part of the trench is greater than a depth of a relatively high impurity region of the main electrode contact region, the relatively high impurity region of the main electrode contact region being defined as a region having an impurity concentration of approximately 1×10¹⁸ cm⁻³ or greater.

4. The method of manufacturing the silicon carbide semiconductor device according to claim 3, wherein inside the trench, a termination position of the curved surface that defines the round part is separated from the base region by at least 0.1 μm.

5. The method of manufacturing the silicon carbide semiconductor device according to claim 3, wherein the thermal oxidation treatment of the inner wall of the trench is performed only one time.

6. The method of manufacturing the silicon carbide semiconductor device according to claim 4, wherein the thermal oxidation treatment of the inner wall of the trench is performed only one time.

7. The method of manufacturing the silicon carbide semiconductor device according to claim 5, wherein the removing of the thermal oxide film removes a layer of the inner wall of the trench with a thickness of 2 nm to 20 nm.
